(19) United States
(12) Patent Application Publication
(10) Pub. No.: US 2026/0293093 A1
(43) Pub. Date: Sep. 24, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Ta-Chuan Liao, Taichung City (TW); Yu-Chien Chiu, Hsinchu County (TW); Wen-Ling Lu, Taoyuan County (TW); Ya-Yun Cheng, Taichung City (TW); Zhiqiang Wu, Chubei (TW)

(21) Appl. No.: 19/083,832

(22) Filed: Mar. 19, 2025

(51) Int. Cl. H10B 12/00

(52) U.S. Cl. CPC H10B 12/315; H10B 12/05; H10B 12/482

(57) ABSTRACT

The present disclosure, in some embodiments, relates to an integrated chip. The integrated chip includes a gate structure over a substrate and a channel structure over the gate structure. A first source/drain contact and a second source/drain contact are disposed over the channel structure and the gate structure. The first source/drain contact is laterally separated from the second source/drain contact along a first direction. A capacitor is electrically coupled to the first source/drain contact. The first source/drain contact has a first length and the second source/drain contact has a second length measured along a second direction that is substantially perpendicular to the first direction. The first length is different than the second length.

### BACKGROUND

Many modern-day electronic devices contain electronic memory configured to store data. Electronic memory may be volatile memory or non-volatile memory. Volatile memory stores data when it is powered, while non-volatile memory is able to store data when power is removed. Dynamic random access memory (DRAM) is a type of volatile semiconductor memory that temporarily stores data. DRAM is typically operated to store files that are used when a computer is running programs or applications. It may be located close to the processor so the computer can access it quickly.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIGS. 1A-1B illustrate some embodiments of an integrated chip structure having a transistor with an asymmetric source/drain design.

FIGS. 2A-2B illustrate some additional embodiments of an integrated chip memory structure having access transistors with an asymmetric source/drain design.

FIGS. 3A-3D illustrate some additional embodiments of an integrated chip memory structure having access transistors with an asymmetric source/drain design.

FIGS. 4A-4C illustrate some additional embodiments of an integrated chip memory structure having access transistors with an asymmetric source/drain design.

FIG. 5 illustrates a top-view of some additional embodiments of an integrated chip memory structure having access transistors with an asymmetric source/drain design.

FIG. 6 illustrates a top-view of some additional embodiments of an integrated chip memory structure having access transistors with an asymmetric source/drain design.

FIGS. 7A-7B illustrate some additional embodiments of an integrated chip memory structure having access transistors with an asymmetric source/drain design.

FIGS. 8A-20B illustrate some embodiments to a method of forming an integrated chip memory structure having access transistors with an asymmetric source/drain design.

FIG. 21 illustrates a flow diagram of some embodiments of a method of forming an integrated chip memory structure having access transistors with an asymmetric source/drain design.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Modern dynamic random-access memory (DRAM) commonly uses a one-transistor, one capacitor (1T1C) memory cell structure. A 1T1C memory cell structure includes a transistor that is configured to control access to a capacitor that stores data. The transistor comprises a gate structure arranged between source and drain regions. 1T1C memory cells may be arranged on an integrated chip within a memory array having rows and columns. The drain regions of memory cells within a row are coupled to a bit-line, while the gate structure of memory cells within a column are coupled to a word-line. During operation, memory cells can be accessed by selectively activating a combination of word-lines and/or bit-lines.

Over time, the size of many integrated chip components has scaled downward to improve integrated chip performance. However, it has been difficult to reduce a size of DRAM cells. This is in-part because a reduction in the size of DRAM cells leads to increased parasitic capacitance. For example, a 1T1C DRAM cell may be susceptible to parasitic capacitance between a gate and a drain (e.g., C_{gd}) and/or unwanted parasitic capacitance that builds upon bit-lines. Such parasitic capacitances can reduce performance of the DRAM cells. For example, a large gate to drain parasitic capacitance can delay memory latency and cause a slow memory read time.

The present disclosure relates to an integrated chip structure comprising a memory array having a 1T1C memory cell structure with an access transistor having an asymmetric source/drain design. In some embodiments, the integrated chip structure comprises a first source/drain contact and a second source/drain contact separated from a gate structure by a channel structure. A capacitor is electrically coupled to the first source/drain contact. The first source/drain contact is laterally separated from the second source/drain contact along a first direction. The first source/drain contact and the second source/drain contact have different lengths measured along a second direction that is substantially perpendicular to the first direction. The different lengths give an access transistor an asymmetric source/drain design, which enables a size of a memory cell to shrink while also reducing parasitic capacitances within the memory cell. For example, the asymmetric design can decrease a memory cell footprint and decrease a gate to drain capacitance, thereby improving performance and decreasing a cost of a memory array.

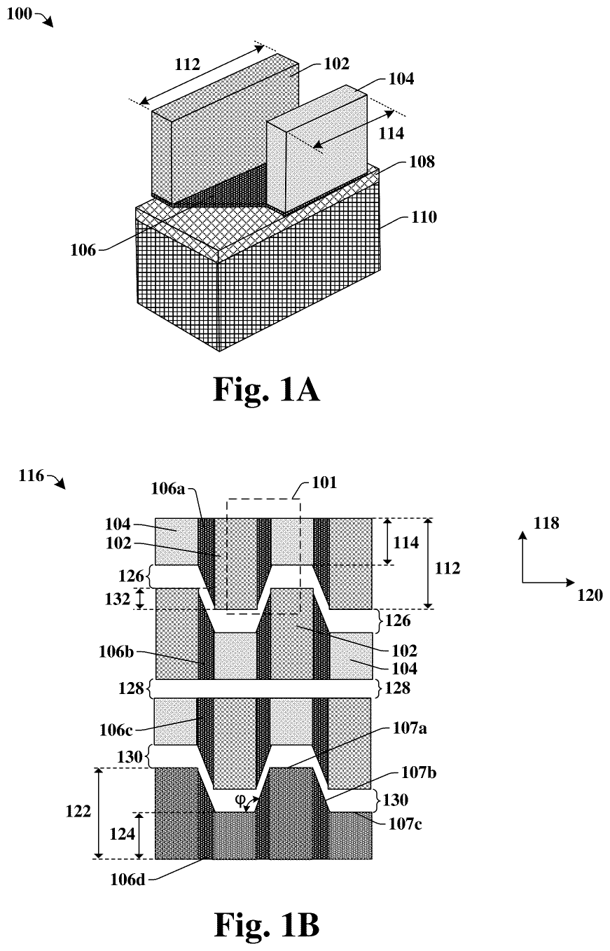

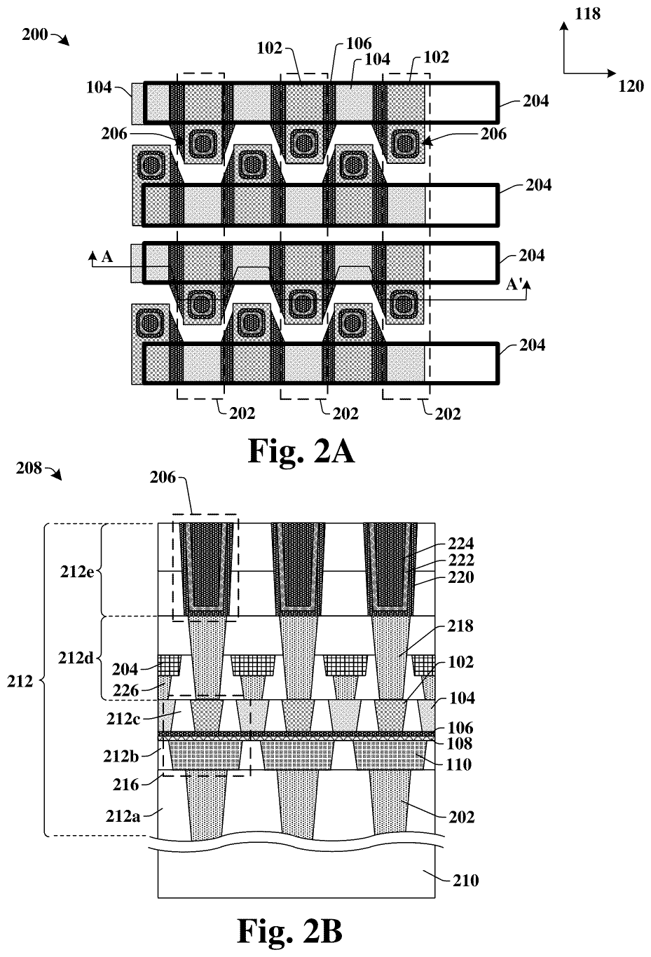

FIGS. 1A-1B illustrate some embodiments of an integrated chip structure having transistors with an asymmetric source/drain design.

FIG. 1A illustrates a three-dimensional view of some embodiments of a transistor 100 with an asymmetric source/drain design.

The transistor 100 comprises a plurality of source/drain contacts 102-104 disposed over a channel structure 106. The plurality of source/drain contacts 102-104 have different lengths. For example, a first one of the source/drain contacts 102-104 may have a first length 112 and a second one of the source/drain contacts 102-104 may have a second length 114 that is different than the first length 112. The channel structure 106 is disposed over a gate dielectric 108. The gate dielectric 108 separates the channel structure 106 from an underlying gate structure 110. During operation, a bias voltage may be selectively applied to the gate structure 110. The bias voltage causes the gate structure 110 to generate an electric field that forms a conductive channel within the channel structure 106. The conductive channel extends between neighboring ones of the plurality of source/drain contacts 102-104.

In some embodiments, the plurality of source/drain contacts 102-104 comprise a source contact 102 and a drain contact 104 disposed over the channel structure 106. The source contact 102 has the first length 112 and the drain contact 104 has the second length 114. The different lengths of the source contact 102 and the drain contact 104 allow for a relatively large current to be provided through the source contact 102 so as to mitigate current loss to a memory cell, while reducing a parasitic capacitance between the gate structure 110 and the drain contact 104 (e.g., to approximately 0.5 times that of memory arrays having symmetric source and drain contacts). Reducing the parasitic capacitance between the gate structure 110 and the drain contact 104 reduces a bit-line capacitance (e.g., since a bit-line capacitance is proportional to a parasitic gate drain capacitance) and thereby can improve performance of an associated memory cell. For example, bit-line capacitance can improve a charge sharing ratio and read noise, decrease memory latency time and improve memory reading speed, etc.

FIG. 1B illustrates a top-view 116 of an integrated chip memory structure having access transistors with an asymmetric source/drain design. In some embodiments, the transistor shown in FIG. 1A may correspond to region 101 of top-view 116.

As shown in top-view 116, the integrated chip memory structure comprises a plurality of channel structures 106a-106d separated along a first direction 118. For example, the plurality of channel structures 106a-106d may comprise a first channel structure 106a, a second channel structure 106b, a third channel structure 106c, and a fourth channel structure 106d. The plurality of channel structures 106a-106d respectively have a width measured along the first direction 118. The width varies between a first width 122 and a second width 124 that is smaller than the first width 122. In some embodiments, the plurality of channel structures 106a-106d respectively have a first side that is substantially straight and an opposing second side that has a winding shape. In some embodiments, the second side includes a first sidewall 107a, a second sidewall 107b, and a third sidewall 107c. The first sidewall 107a and the third sidewall 107c extend in parallel (e.g., in a second direction 120 that is perpendicular or substantially perpendicular to the first direction 118), while the second sidewall 107b is angled to extend between the first sidewall 107a and the third sidewall 107c. In some embodiments, the second sidewall 107b is separated from the third sidewall 107c by an obtuse angle φ measured outside of the plurality of channel structures 106a-106d.

The first channel structure 106a is separated from the second channel structure 106b by a first region 126 that has a tortuous shape (e.g., a serpentine shape or a winding shape). The second channel structure 106b is separated from the third channel structure 106c by a second region 128 that has a rectangular shape. The third channel structure 106c is separated from the fourth channel structure 106d by a third region 130 that has a tortuous shape. In some embodiments, the tortuous shape of the first region 126 and/or the third region 130 may extend over a larger distance along the first direction 118 than along the second direction 120 in the top-view 116.

A plurality of source/drain contacts 102-104 are arranged over the plurality of channel structures 106a-106d. The plurality of source/drain contacts 102-104 have different lengths. For example, in some embodiments the plurality of source/drain contacts 102-104 include source contacts 102 having the first length 112 and drain contacts 104 having the second length 114. In some embodiments, the first length 112 is substantially equal to the first width 122 and the second length 114 is substantially equal to the second width 124. In some embodiments, the plurality of channel structures 106a-106d respectively comprise a region that is between closest neighboring drain contacts 104 (e.g., that is partially below a source contact 102) and that has a trapezoidal shape.

The plurality of source/drain contacts 102-104 are arranged in columns extending in the first direction 118 and rows extending in the second direction 120. Within both the rows and the columns, the plurality of source contacts 102 are interleaved with the plurality of drain contacts 104. For example, a first row of source/drain contacts 102-104 extending in the second direction 120 over the first channel structure 106a includes source contacts 102 interleaved with drain contacts 104. Similarly, a first column of source/drain contacts 102-104 extending in the first direction 118 over the plurality of channel structures 106a-106d includes source contacts 102 interleaved with drain contacts 104.

In some embodiments, first sides of source/drain contacts 102-104 within a row are aligned with one another, while second sides of the source/drain contacts 102-104 within the row are offset by a non-zero distance from one another (e.g., the source contacts 102 extend past an end of the second side of the drain contacts 104 along the first direction 118). In some embodiments, the source contacts 102 within adjacent rows laterally overlap one another by a non-zero distance 132 along the first direction 118. By overlapping the source contacts 102 within adjacent rows, a density of memory cells within the memory array can be increased, thereby decreasing a size of memory array (e.g., by approximately 20%) and thus reducing a cost of the memory without negatively impacting parasitic capacitances within the memory array.

FIGS. 2A-2B illustrate some additional embodiments of an integrated chip memory structure having access transistors with an asymmetric source/drain design.

FIG. 2A illustrates a top-view 200 of some additional embodiments of an integrated chip memory structure having access transistors with an asymmetric source/drain design.

As shown in top-view 200, the integrated chip memory structure comprises a plurality of source contacts 102 and a plurality of drain contacts 104 disposed over a plurality of channel structures 106. A plurality of word-lines 202 are disposed below the channel structure 106. The plurality of word-lines 202 continuously extend past the plurality of channel structures 106. In some embodiments, the plurality of word-lines 202 may have a width that is greater than a width of an overlying one of the plurality of source contacts 102. In some embodiments, the plurality of word-lines 202 may extend in a straight line along a first direction 118. In other embodiments (not shown), the plurality of word-lines 202 may be slanted (e.g., extend along an acute angle measured with respect to the first direction 118). In yet other embodiments (not shown), the plurality of word-lines 202 may have a winding shape.

A plurality of bit-lines 204 are disposed over the plurality of drain contacts 104. The plurality of bit-lines 204 extend in a second direction 120 over respective ones of the plurality of channel structures 106. In some embodiments, the plurality of bit-lines 204 may have a width that is substantially equal to a length of an underlying one of the plurality of drain contacts 104. In some embodiments, the different lengths of the plurality of source contacts 102 and the plurality of drain contacts 104 allow for some of the plurality of bit-lines 204 to be separated from one another by larger spaces than that of memory cells having symmetric source and drain contacts. This can decrease a parasitic bit-line capacitance (e.g., to approximately 0.7 times that of a memory array having symmetric source and drain contacts), thereby improving performance of a memory cell (e.g., improving a charge sharing ratio and read noise).

The plurality of word-lines 202 are electrically coupled to gate structures (not shown) that are arranged below the channel structures 106 and that are configured to control the flow of charge carriers between neighboring source and drain contacts. In some embodiments, the plurality of word-lines 202 may directly contact the gate structures, while in other embodiments the plurality of word-lines may be electrically coupled to the gate structures by one or more gate contacts (e.g., respective gate structures may be coupled to an underlying word-line by a gate contact). The plurality of bit-lines 204 are electrically coupled to the plurality of drain contacts 104. In some embodiments, the plurality of bit-lines 204 are electrically coupled to the plurality of drain contacts 104 by one or more conductive vias (not shown). In some embodiments, the plurality of source contacts 102 are coupled to capacitors 206 disposed over the source contacts 102. The capacitors 206 are configured to store an electric charge that is proportional to a data state that is to be stored. For example, the capacitors 206 may store a first charge that corresponds to a first data state (e.g., a logical ‘0’) or a second charge that corresponds to a second data state (e.g., a logical ‘1’).

FIG. 2B illustrates a cross-sectional view 208 of some embodiments of an integrated chip memory structure taken along cross-sectional line A-A′ of FIG. 2A.

As shown in cross-sectional view 208, the integrated chip memory structure comprises an inter-level dielectric (ILD) structure 212 disposed over a substrate 210. In some embodiments, the ILD structure 212 comprises a plurality of ILD layers stacked onto one another. In some embodiments, the plurality of ILD layers may comprise one or more of silicon dioxide, carbon doped silicon oxide (SiCOH), phosphosilicate glass (PSG), borophosphosilicate glass (BPSG), borosilicate glass (BSG), fluorosilicate glass (FSG), undoped silicate glass (USG), and/or the like.

A plurality of word-lines 202 are disposed within a first ILD layer 212a of the ILD structure 212. The plurality of word-lines 202 include interconnect wires disposed within the first ILD layer 212a. A plurality of gate structures 110 are arranged within a second ILD layer 212b over the first ILD layer 212a and the plurality of word-lines 202. In some embodiments, the plurality of gate structures 110 may comprise a conductive material, such as tantalum nitride (TaN), titanium nitride (TiN), tungsten (W), aluminum (Al), polysilicon, and/or the like. A gate dielectric 108 is disposed over the second ILD layer 212b and on the plurality of gate structures 110. A channel structure 106 is disposed over the gate dielectric 108.

A plurality of source/drain contacts 102-104 are arranged within a third ILD layer 212c over the channel structure 106. The plurality of source/drain contacts 102-104 alternate between the plurality of source contacts 102 and the plurality of drain contacts 104. Collectively, the plurality of source/drain contacts 102-104, the gate structure 110, and the channel structure 106 form an access transistor 216.

A first plurality of upper interconnects 218 are arranged within a first upper ILD structure 212d over the plurality of source/drain contacts 102-104 and the third ILD layer 212c. The first plurality of upper interconnects 218 couple the source contacts 102 to the plurality of capacitors 206, which are arranged within a second upper ILD structure 212e over the first upper ILD structure 212d. The plurality of capacitors 206 respectively include a lower capacitor electrode 220 separated from an upper capacitor electrode 224 by a capacitor dielectric 222. A second plurality of upper interconnects 226 are also arranged within the first upper ILD structure 212d. The second plurality of upper interconnects 226 couple the plurality of drain contacts 104 to the bit-lines 204, which may be arranged within the first upper ILD structure 212d. In some embodiments, the first plurality of upper interconnects 218 may have a larger height than the second plurality of upper interconnects 226.

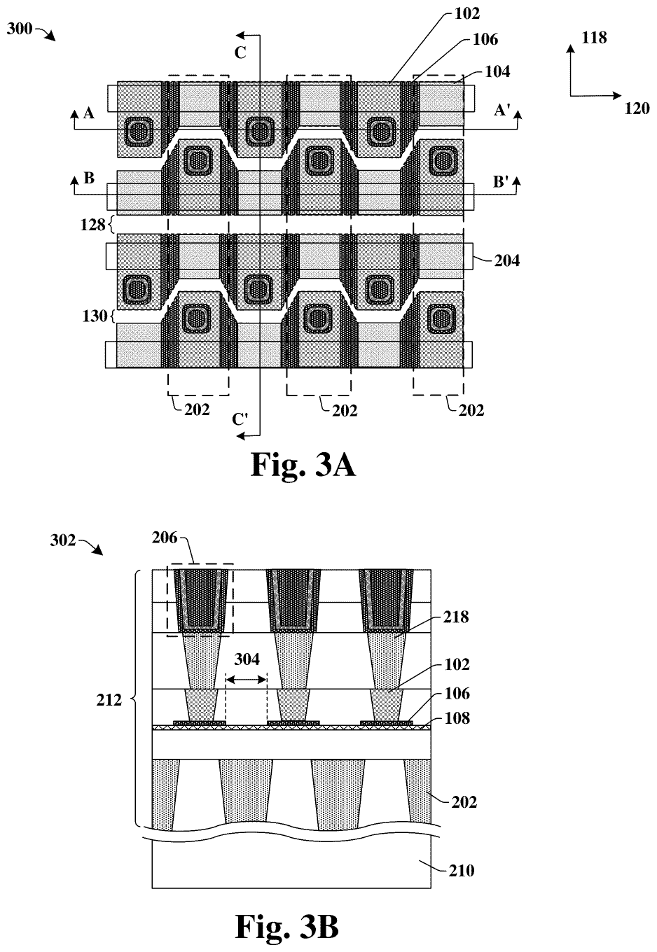

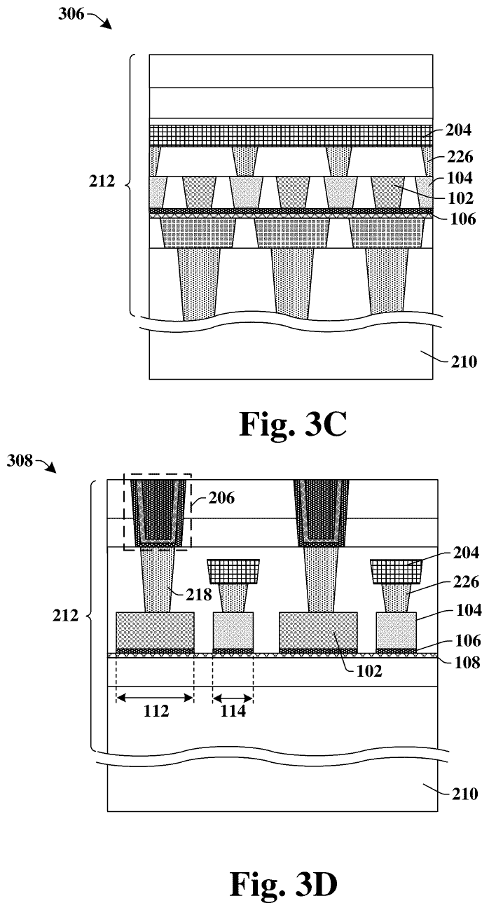

FIGS. 3A-3D illustrate some additional embodiments of an integrated chip memory structure having access transistors with an asymmetric source/drain design.

FIG. 3A illustrates a top-view 300 of some embodiments of an integrated chip memory structure having access transistors with an asymmetric source/drain design.

As shown in top-view 300, a plurality of source contacts 102 and a plurality of drain contacts 104 are disposed over a plurality of channel structures 106. A plurality of word-lines 202 are arranged below the plurality of channel structures 106. The plurality of word-lines 202 extend past the plurality of channel structures 106 along a first direction 118. A plurality of bit-lines 204 extend in a second direction 120 over respective ones of the plurality of channel structures 106.

FIG. 3B illustrates a cross-sectional view 302 of some embodiments of an integrated chip memory structure taken along cross-sectional line A-A′ of FIG. 3A.

As shown in cross-sectional view 302, the plurality of source contacts 102 are disposed over discrete segments of a channel structure 106. The discrete segments of the channel structure 106 are separated from one another along a first distance 304. In some embodiments, the first distance 304 is directly over a word-line 202. A first plurality of upper interconnects 218 couple the plurality of source contacts 102 to overlying capacitors 206. In some embodiments, the first plurality of upper interconnects 218 may comprise conductive vias.

FIG. 3C illustrates a cross-sectional view 306 of some embodiments of an integrated chip memory structure taken along cross-sectional line B-B′ of FIG. 3A.

As shown in cross-sectional view 306, the plurality of source contacts 102 and the plurality of drain contacts 104 are disposed over the channel structure 106. A second plurality of upper interconnect 226 couple the plurality of drain contacts 104 to an overlying bit-line 204.

FIG. 3D illustrates a cross-sectional view 308 of some embodiments of an integrated chip memory structure taken along cross-sectional line C-C′ of FIG. 3A.

As shown in cross-sectional view 308, the plurality of source contacts 102 are interleaved between the plurality of drain contacts 104 over the plurality of channel structures 106. The plurality of source contacts 102 have a first length 112 that is greater than a second length 114 of the plurality of drain contacts 104. The plurality of channel structures 106 below the plurality of source contacts 102 have a greater width than the plurality of channel structures 106 below the plurality of drain contacts 104. Bit-lines 204 extend over the plurality of drain contacts 104.

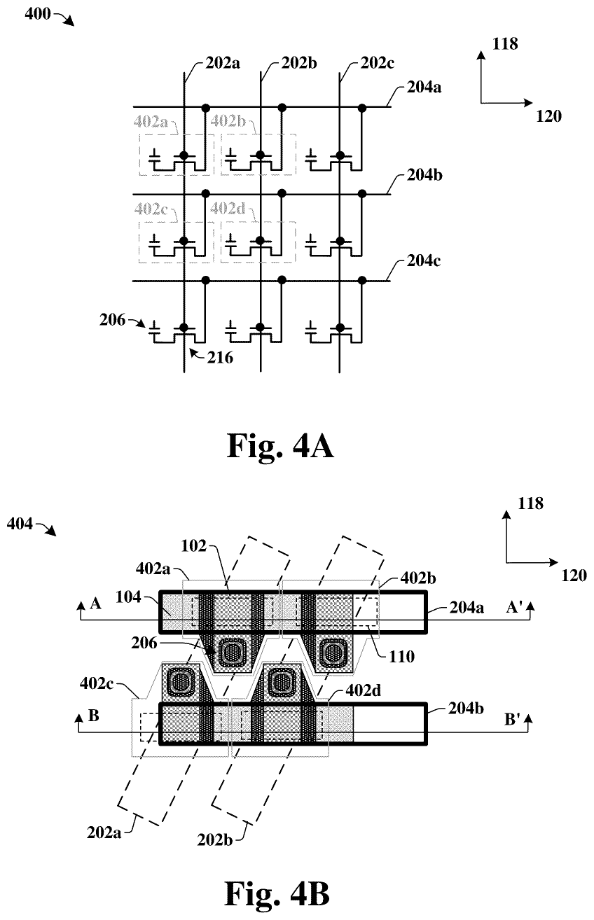

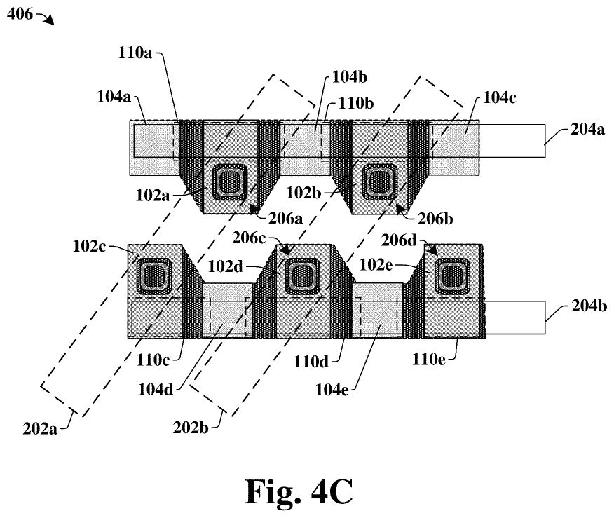

FIG. 4A illustrates a schematic diagram 400 of some embodiments of a disclosed integrated chip memory structure.

As shown in the schematic diagram 400, the integrated chip structure comprises a memory array including a plurality of memory cells 402a-402d arranged within columns (extending along a first direction 118) and rows (extending along a second direction 120). The plurality of memory cells 402a-402d respectively comprise a capacitor 206 and an access transistor 216, which is configured to control access to the capacitor 206.

FIG. 4B illustrates a top-view 404 showing some embodiments corresponding to a section of the schematic diagram 400 of FIG. 4A.

As shown in top-view 404, gate structures 110 within transistors of memory cells 402a and 402c are operably coupled to a first word-line 202a of a plurality of word-lines 202a-202b, while the gate structures within transistors of memory cells 402b and 402d are operably coupled to a second word-line 202b of the plurality of word-lines 202a-202b.

In some embodiments, the gate structures 110 within adjacent rows are laterally staggered (along the second direction 120) from one another. Staggering the gate structure 110 can reduce a parasitic capacitance between the gate structures (e.g., to approximately 0.8 times that of a memory array having symmetric source and drain contacts), thereby improving a cycle time of the integrated chip memory structure. The gate structures 110 laterally extend along the second direction 120 from directly below one or more of the plurality of source contacts 102 to directly below one or more of the plurality of drain contacts 104.

The drain contacts 104 within a first row are operably coupled to a first bit-line 204a of a plurality of bit-lines 204a-204b and the drain contacts 104 within a second row are operably coupled to a second bit-line 204b of a plurality of bit-lines 204a-204b. The source contacts 102 are coupled to overlying capacitors 206. The word-lines 202 and the bit-lines 204 are further coupled to control circuitry (not shown), which is configured to selectively apply signals to the plurality of word-lines 202a-202b and/or the plurality of bit-lines 204a-204b to access (e.g., write data to and/or read data from) one or more of the plurality of memory cells 402a-402d.

For example, FIG. 4C illustrates a top-view 406 of a portion of a memory array comprising a plurality of memory cells. To access a first capacitor 206a within the first memory cell, control circuitry can activate a first word-line 202a and a first bit-line 204a. Activating the first word-line 202a will cause a first gate structure 110a to form conductive channels within the channel structure 106 between a first source contact 102a and a first drain contact 104a and between a second source contact 102b and a second drain contact 104b. Similarly, to access a second capacitor 206d within the second memory cell, control circuitry can activate the second word-line 202b and the second bit-line 204b. Activating the second word-line 202b will cause a fourth gate structure 110d to form conductive channels within the channel structure 106 between a source contact 102d and drain contact 104d and between source contact 102d and drain contact 104e.

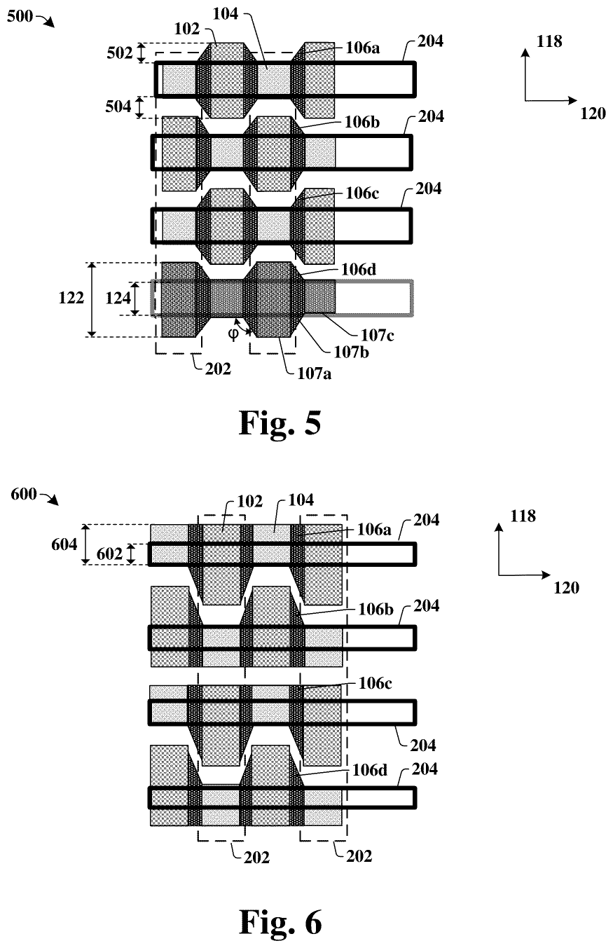

FIG. 5A illustrates a top-view 500 of some additional embodiments of an integrated chip memory structure having an asymmetric source/drain design.

As shown in top-view 500, the integrated chip memory structure comprises a plurality of channel structures 106a-106d separated along a first direction 118. Neighboring ones of the plurality of channel structures 106a-106d are separated from the one another by a region having a tortuous (e.g., serpentine or winding) shape. In some embodiments, the plurality of channel structures 106a-106d respectively have first and second sides that have a winding shape. The winding shapes of the first and second sides cause the plurality of channel structure 106a-106d to respectively have a width that varies between a first width 122 and a second width 124. In some embodiments, the first and second sides respectively include a first sidewall 107a, a second sidewall 107b, and a third sidewall 107c. The first sidewall 107a and the third sidewall 107c extend in a same direction (e.g., in a first direction 118), while the second sidewall 107b is angled to extend between the first sidewall 107a and the third sidewall 107c. In some embodiments, the first sidewall 107a is separated from the second sidewall 107b by an obtuse angle φ.

A plurality of source contacts 102 and a plurality of drain contacts 104 are arranged over respective ones of the plurality of channel structures 106a-106d. The plurality of source contacts 102 are arranged over parts of the plurality of channel structures 106a-106d that have the first width 122 and the plurality of drain contacts 104 are arranged over parts of the plurality of channel structures 106a-106d that have the second width 124. In some embodiments, the plurality of source contacts 102 extend along the first direction 118 to non-zero distances, 502 and 504, past opposing ends of the plurality of drain contacts 104. A plurality of bit-lines 204 extend over respective ones of the plurality of channel structures 106a-106d. In some embodiments, the plurality of bit-lines 204 may respectively have a width that is substantially equal to a length of respective ones of the plurality of drain contacts 104.

FIG. 6 illustrates a top-view 600 of some additional embodiments of an integrated chip memory structure having an asymmetric source/drain design.

As shown in top-view 600, the integrated chip memory structure comprises a plurality of channel structure 106a-106d separated along a first direction 118. The plurality of channel structures 106a-106d are separated from neighboring channel structures by a first region that has a tortuous (e.g., serpentine or winding) shape and by a second region that has a rectangular shape.

A plurality of bit-lines 204 extend over respective ones of the plurality of channel structures 106a-106d. In some embodiments, the plurality of bit-lines 204 may respectively have a width 602 that is less than a length 604 of the drain contacts 104, so as to reduce parasitic capacitance between neighboring bit-lines.

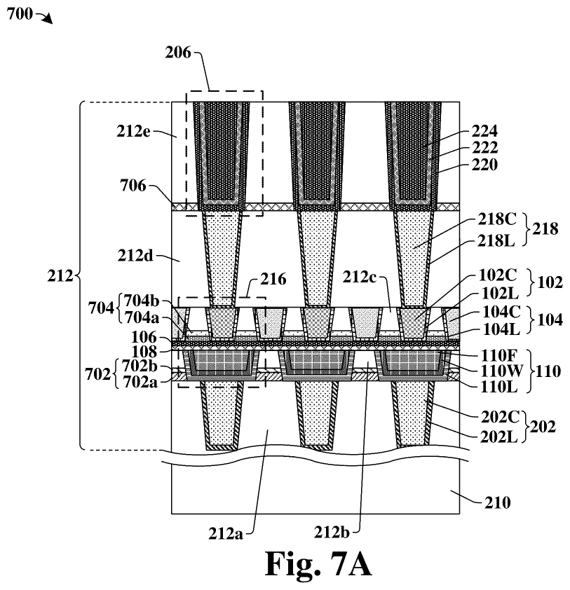

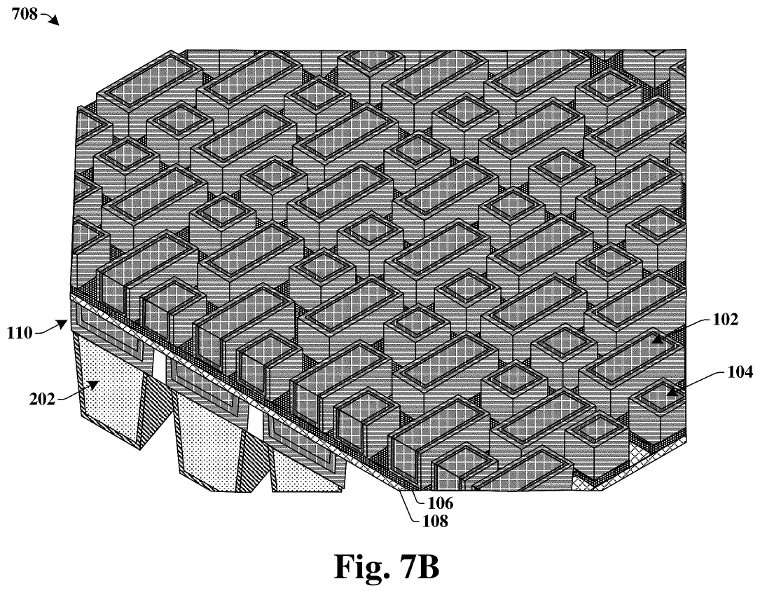

FIGS. 7A-7B illustrate some additional embodiments of an integrated chip memory structure comprising access transistors having an asymmetric source/drain design.

FIG. 7A illustrates a cross-sectional view 700 of some additional embodiments of an integrated chip memory structure comprising access transistors having an asymmetric source/drain design.

As shown in cross-sectional view 700, the integrated chip comprises an inter-level dielectric (ILD) structure 212 disposed over a substrate 210. In some embodiments, the ILD structure 212 comprises a plurality of ILD layers stacked onto one another. A plurality of word-lines 202 are disposed within the ILD structure 212. The plurality of word-lines 202 include interconnect wires having a conductive material 202C surrounded by a diffusion barrier 202L. In some embodiments, the conductive material 202C may comprise copper, aluminum, ruthenium, tungsten, and/or the like. In some embodiments, the diffusion barrier 202L may comprise tantalum, tantalum nitride, titanium, titanium nitride, and/or the like.

A plurality of gate structures 110 are arranged within a second ILD layer 212b over the first ILD layer 212a and the plurality of word-lines 202. In some embodiments, the plurality of gate structures 110 may comprise a gate liner 110L, a work function metal 110W over the gate liner 110L, and a conductive fill 110F over the work function metal 110W. In some embodiments, the gate liner 110L may comprise tantalum, tantalum nitride, titanium, titanium nitride, and/or the like. In some embodiments, the work function metal 110W may comprise tantalum, titanium, hafnium, zirconium, and/or the like. In some embodiments, the conductive fill 110F may comprise aluminum, copper, and/or the like.

A gate dielectric 108 is arranged over the gate structures 110 and a channel structure 106 is disposed over the gate dielectric 108. In some embodiments, the gate dielectric 108 may comprise an oxide. For example, the gate dielectric 108 may comprise hafnium oxide (HfO₂), silicon oxide (SiO₂), aluminum oxide (Al₂O₃), silicon oxynitride (SiON), and/or the like. In some embodiments, the channel structure 106 may comprise a semiconductor oxide. In some embodiments, the channel structure 106 may comprise an n-type channel including one or more of indium-gallium-zinc-oxide (IGZO), zinc oxide (ZnO), indium oxide (In₂O₃), tin oxide (SnO₂). In other embodiments, the channel structure 106 may comprise a p-type channel including one or more of nickel oxide (NiO), copper oxide (Cu₂O), copper aluminum oxide (CuAlO₂), copper gallium oxide (CuGaO₂), copper indium oxide (CuInO₂), strontium copper oxide (SrCu₂O₂), and tin oxide (SnO).

A plurality of source/drain contacts 102-104 are arranged within a third ILD layer 212c over the channel structure 106. The plurality of source/drain contacts 102-104 alternate between source contacts 102 and drain contacts 104. In some embodiments, the source/drain contacts 102-104 may comprise one or more of tantalum nitride (TaN), titanium nitride (TiN), tungsten (W), aluminum (Al), polysilicon, ruthenium (Ru), cobalt (Co), copper (Cu), and/or the like. Collectively, the plurality of source/drain contacts 102-104, the gate structure 110, and the channel structure 106 form an access transistor 216.

A first plurality of upper interconnects 218 are arranged within a first upper ILD structure 212d over the plurality of source/drain contacts 102-104 and the third ILD layer 212c. The first plurality of upper interconnects 218 couple the source contacts 102 to the plurality of capacitors 206, which are arranged within a second upper ILD structure 212e over the first upper ILD structure 212d. The plurality of capacitors 206 respectively include a lower capacitor electrode 220 separated from an upper capacitor electrode 224 by a capacitor dielectric 222.

In some embodiments, the ILD structure 212 may comprise one or more ILD layers that are vertically separated from one another by an etch stop structure. For example, a first etch stop structure 702 that surrounds a part of the gate structures 110 may separate the first ILD layer 212a from the second ILD layer 212b. In some embodiments, the first etch stop structure 702 may comprise a first etch stop layer 702a and a second etch stop layer 702b over the first etch stop layer 702a. In some embodiments, the first etch stop layer 702a and the second etch stop layer 702b may comprise one or more of silicon nitride, silicon carbide, silicon oxynitride, and/or the like. In some embodiments, a second etch stop structure 704 may be disposed between the channel structure 106 and a third ILD layer 212c. In some embodiments, the second etch stop structure 704 may comprise a first etch stop layer 704a and a second etch stop layer 704b over the first etch stop layer 704a. In some embodiments, the first etch stop layer 704a and the second etch stop layer 704b may comprise one or more of silicon nitride, silicon carbide, silicon oxynitride, and/or the like. In some embodiments, a third etch stop structure 706 may be disposed between a first upper ILD structure 212d and a second upper ILD structure 212e. In some embodiments, the third etch stop structure 706 may comprise one or more of silicon nitride, silicon carbide, silicon oxynitride, and/or the like.

FIG. 7B illustrates a three-dimensional view 708 of some additional embodiments of an integrated chip memory structure of FIG. 7A.

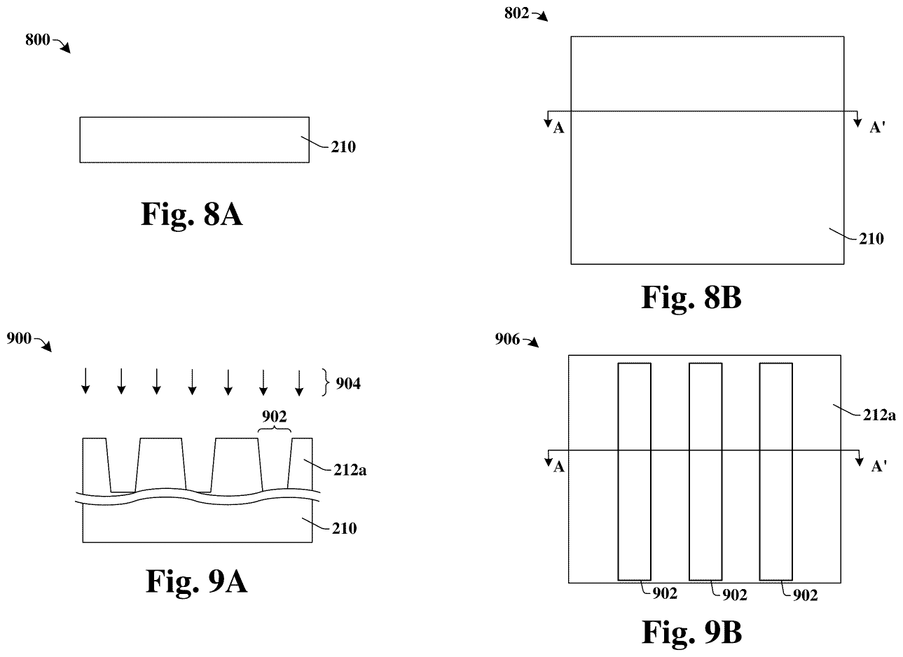

FIGS. 8A-20B illustrate some embodiments of a method of forming an integrated chip memory structure having access transistors with an asymmetric source/drain design. Although the embodiments shown in FIGS. 8A-20B are described with reference to a method, it will be appreciated that the structures shown in FIGS. 8A-20B are not limited to the method of formation but rather may stand alone separate of the method.

As shown in cross-sectional view 800 of FIG. 8A and top-view 802 of FIG. 8B, a substrate 210 is provided. In various embodiments, the substrate 210 may be any type of substrate (e.g., silicon, SiGe, SOI, etc.), such as a semiconductor wafer, as well as any other type of semiconductor and/or epitaxial layers, associated therewith.

As shown in cross-sectional view 900 of FIG. 9A and top-view 906 of FIG. 9B, a first inter-level dielectric (ILD) layer 212a is formed over the substrate 210. In some embodiments, the first ILD layer 212a may be formed by one or more deposition processes (e.g., a physical vapor deposition (PVD) process, a chemical vapor deposition (CVD) process, a plasma enhanced CVD (PE-CVD) process, and/or the like). In some embodiments, the first ILD layer 212a may comprise silicon dioxide, carbon doped silicon oxide (SiCOH), phosphosilicate glass (PSG), borophosphosilicate glass (BPSG), borosilicate glass (BSG), fluorosilicate glass (FSG), undoped silicate glass (USG), and/or the like. In some embodiments (not shown), one or more additional ILD layers may be disposed between the first ILD layer 212a and the substrate 210.

A patterning process is performed on the first ILD layer 212a to form a plurality of word-line openings 902 respectively formed by sidewalls and a horizontally extending surface of the first ILD layer 212a. In some embodiments, the patterning process may comprise a lithography process followed by an etching process that selectively exposes the first ILD layer 212a to an etchant 904. In some embodiments, the etchant 904 may comprise a dry etchant (e.g., having a fluorine chemistry, a chlorine chemistry, or the like). In other embodiments, the etchant 904 may comprise a wet etchant (e.g., comprising hydrofluoric acid, potassium hydroxide, or the like).

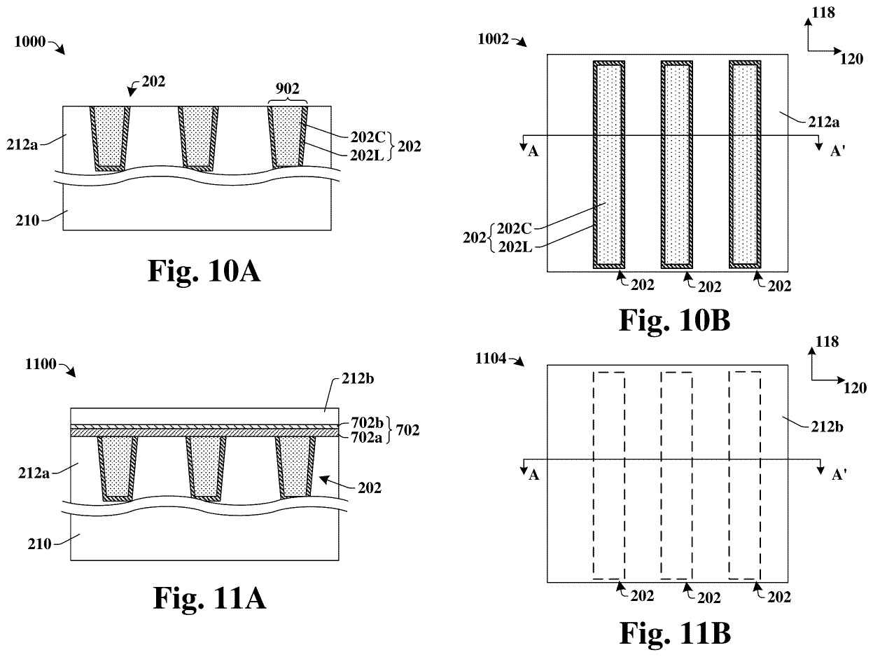

As shown in cross-sectional view 1000 of FIG. 10A and top-view 1002 of FIG. 10B, a diffusion barrier 202L is formed within the plurality of word-line openings 902. A conductive material 202C is formed on the diffusion barrier 202L and within the plurality of word-line openings 902. A planarization process (e.g., a chemical mechanical planarization (CMP) process) is performed to remove parts of the diffusion barrier 202L and the conductive material 202C that are over the first ILD layer 212a. The planarization process forms a plurality of word-lines 202 within the first ILD layer 212a. In some embodiments, the plurality of word-lines 202 may continuously extend along a first direction 118 and be separated from one another along a second direction 120 that is substantially perpendicular to the first direction 118. In other embodiments (not shown), the plurality of word-lines 202 may be slanted (e.g., extend along an acute angle measured with respect to the first direction 118) and be separated from one another along the second direction 120.

As shown in cross-sectional view 1100 of FIG. 11A and top-view 1104 of FIG. 11B, a first etch stop structure 702 is formed over the first ILD layer 212a and the plurality of word-lines 202. In some embodiments, the first etch stop structure 702 may comprise a first etch stop layer 702a and a second etch stop layer 702b respectively formed by one or more deposition processes (e.g., a PVD process, a CVD process, a PE-CVD process, and/or the like). In some embodiments, the first etch stop layer 702a and/or the second etch stop layer 702b may comprise one or more of silicon nitride, silicon carbide, silicon oxynitride, and/or the like.

A second ILD layer 212b is formed over the first etch stop structure 702. In some embodiments, the second ILD layer 212b may be formed by one or more deposition processes (e.g., a PVD process, a CVD process, a PE-CVD process, and/or the like). In some embodiments, the second ILD layer 212b may comprise one or more of silicon dioxide, SiCOH, PSG, BPSG, BSG, FSG, USG, or the like.

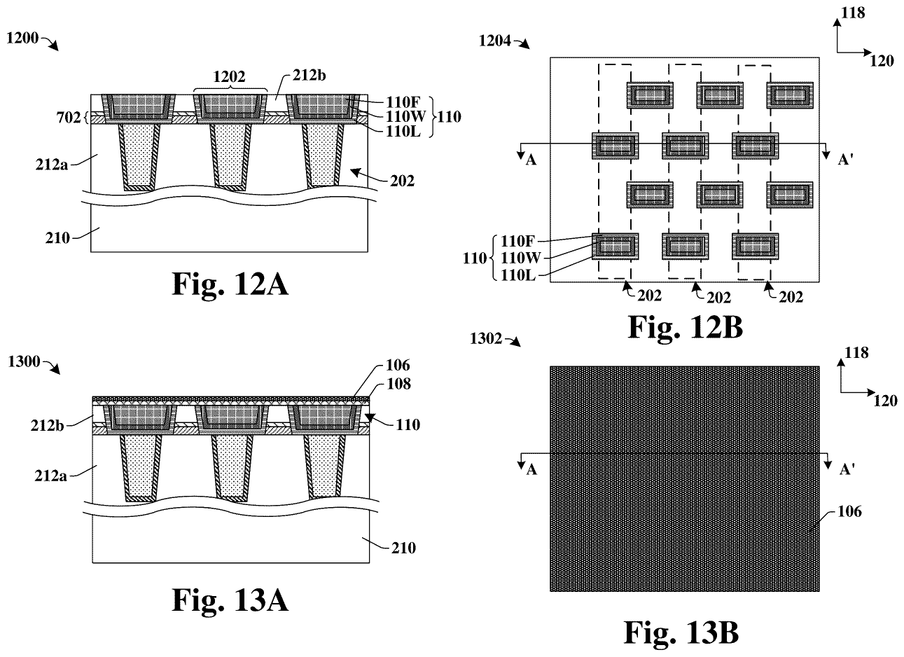

As shown in cross-sectional view 1200 of FIG. 12A and top-view 1204 of FIG. 12B, a plurality of gate structures 110 are formed within the second ILD layer 212b and over the plurality of word-lines 202. In some embodiments, the plurality of word-lines 202 may continuously extend along the first direction 118 below two or more of the plurality of gate structures 110. In some embodiments, the plurality of gate structures 110 are formed by performing a patterning process on the second ILD layer 212b. The patterning process etches through the second ILD layer 212b and the first etch stop structure 702 to form a plurality of gate structure openings 1202. The plurality of gate structures 110 are formed within the plurality of gate structure openings 1202.

In some embodiments, the plurality of gate structures 110 may be formed by forming a gate liner 110L, a work function metal 110W over the gate liner 110L, and a conductive fill 110F over the work function metal 110W. A planarization process (e.g., a CMP process) is performed to form the plurality of gate structures 110 by removing parts of the gate liner 110L, the work function metal 110W, and the conductive fill 110F that are over the second ILD layer 212b. In some embodiments, the gate liner 110L may comprise tantalum, tantalum nitride, titanium, titanium nitride, and/or the like. In some embodiments, the work function metal 110W may comprise tantalum, titanium, hafnium, zirconium, and/or the like. In some embodiments, the conductive fill 110F may comprise aluminum, copper, and/or the like.

As shown in cross-sectional view 1300 of FIG. 13A and top-view 1302 of FIG. 13B, a gate dielectric 108 is formed over the second ILD layer 212b and the plurality of gate structures 110. In some embodiments, the gate dielectric 108 may be formed by one or more deposition processes (e.g., a PVD process, a CVD process, a PE-CVD process, and/or the like). In some embodiments, the gate dielectric 108 may comprise an oxide. For example, the gate dielectric 108 may comprise hafnium oxide (HfO₂), silicon oxide (SiO₂), aluminum oxide (Al₂O₃), silicon oxynitride (SiON), and/or the like.

A channel structure 106 is formed over the gate dielectric 108. In some embodiments, the channel structure 106 may be formed by one or more deposition processes (e.g., a PVD process, a CVD process, a PE-CVD process, and/or the like). In some embodiments, the channel structure 106 may comprise a semiconductor oxide. For example, the channel structure 106 may comprise one or more of indium-gallium-zinc-oxide (IGZO), zinc oxide (ZnO), indium oxide (In₂O₃), tin oxide (SnO₂), nickel oxide (NiO), copper oxide (Cu₂O), copper aluminum oxide (CuAlO₂), copper gallium oxide (CuGaO₂), copper indium oxide (CuInO₂), strontium copper oxide (SrCu₂O₂), and tin oxide (SnO).

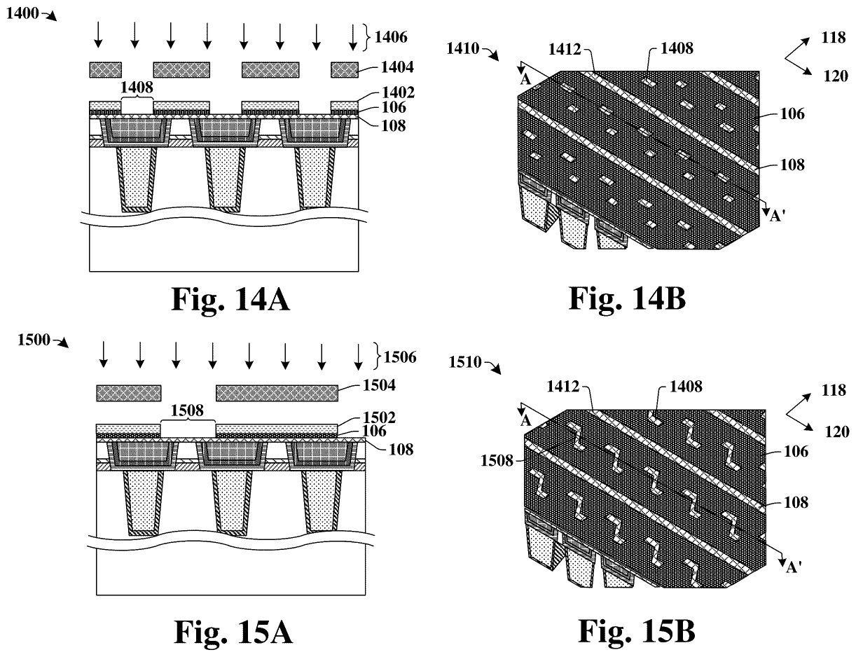

In some embodiments, the channel structure 106 may be patterned according to multiple patterning processes. For example, FIGS. 14A-16B illustrates some embodiments of a channel structure 106 patterned according to three separate patterning processes. Multiple patterning processes may be used to pattern the channel structure 106 for lithography systems that use extreme ultraviolet (EUV) radiation or deep ultraviolet radiation (DUV), for example. In other embodiments (not shown), the channel structure 106 may be patterned using spacer double patterning or e-beam lithography to achieve the same shape without using multiple patterning processes.

As shown in cross-sectional view 1400 of FIG. 14A and three-dimensional view 1410 of FIG. 14B, a first channel patterning process is performed on the channel structure 106 to remove first segments of the channel structure 106 extending along the second direction 120. Removal of the first segments of the channel structure 106 results in a first plurality of openings 1408 that extend along the second direction 120 and in a second plurality of openings 1412 that also extend along the second direction 120. The second plurality of openings 1412 continuously extend past the first plurality of openings 1408 along the second direction 120.

In some embodiments, the first channel patterning process may comprise a first lithography process that selectively exposes a first photosensitive masking material 1402 to electromagnetic radiation 1406 (e.g., extreme ultraviolet (EUV) radiation) according to a first photomask 1404, a development process that removes parts (e.g., exposed parts) of the first photosensitive masking material 1402, and an etching process that selectively exposes the channel structure 106 to an etchant according to the first photosensitive masking material 1402 after the development process.

As shown in cross-sectional view 1500 of FIG. 15A and three-dimensional view 1510 of FIG. 15B, a second channel patterning process is performed on the channel structure 106 to remove second segments of the channel structure 106 extending along a third direction that is different than the first direction 118 and the second direction. In some embodiments, the third direction may be angled with respect to the second direction 120 at an angle that is between approximately 30° and approximately 60°, that is approximately 45°, or other similar values, as measured in a plan-view. Removal of the second segments of the channel structure 106 results in a second plurality of openings 1508 that extend along the third direction and that are contiguous with the first plurality of openings 1408.

In some embodiments, the second channel patterning process may comprise a second lithography process that selectively exposes a second photosensitive masking material 1502 to electromagnetic radiation 1506 (e.g., EUV radiation) according to a second photomask 1504, a development process that removes parts (e.g., exposed parts) of the second photosensitive masking material 1502, and an etching process that selectively exposes the channel structure 106 to an etchant according to the second photosensitive masking material 1502 after the development process.

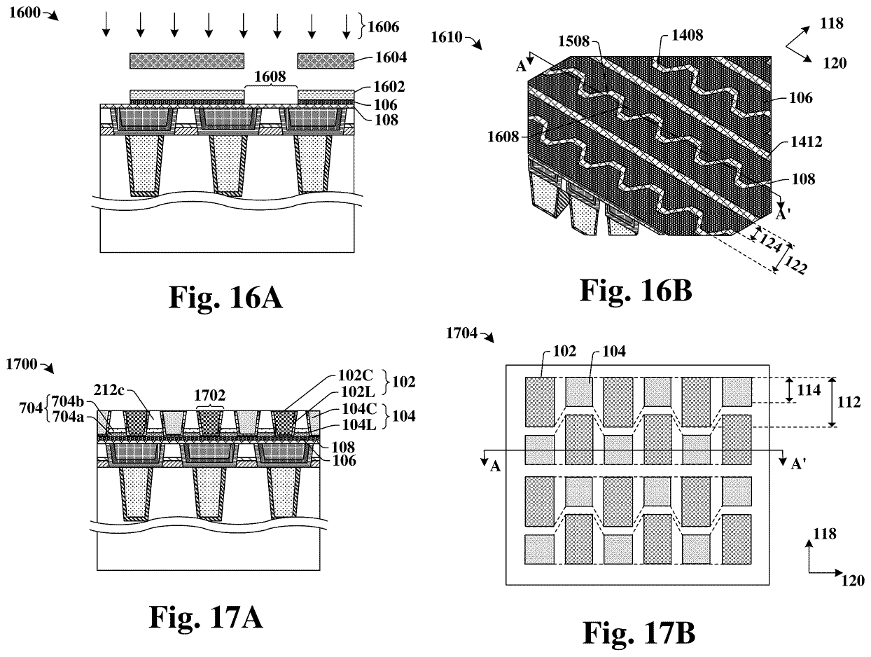

As shown in cross-sectional view 1600 of FIG. 16A and three-dimensional view 1610 of FIG. 16B, a third channel patterning process is performed on the channel structure 106 to remove third segments of the channel structure 106 extending along a fourth direction that is different than the first direction 118, the second direction 120, and the third direction. In some embodiments, the fourth direction may be angled with respect to the second direction 120 at an angle that is between approximately 30° and approximately 60°, that is approximately 45°, or other similar values, as measured in a plan-view. In some embodiments, the fourth direction may be perpendicular to or substantially perpendicular to third direction in a plan-view. Removal of the third segments of the channel structure 106 results in a third plurality of openings 1608 that extend along the fourth direction and that are contiguous with the first plurality of openings 1408 and the second plurality of openings 1508. Collectively, the first plurality of openings 1408, the second plurality of openings 1508, and the third plurality of openings 1608 form a first opening that has a tortuous (e.g., serpentine or winding) shape. The first opening causes the channel structure 106 to have a width that varies between a first width 122 and a second width 124 over the second direction 120.

In some embodiments, the third channel patterning process may comprise a third lithography process that selectively exposes a third photosensitive masking material 1602 to electromagnetic radiation 1606 (e.g., EUV radiation) according to a third photomask 1604, a development process that removes parts (e.g., exposed parts) of the third photosensitive masking material 1602, and an etching process that selectively exposes the channel structure 106 to an etchant according to the third photosensitive masking material 1602 after the development process.

As shown in cross-sectional view 1700 of FIG. 17A and top-view 1704 of FIG. 17B, a second etch stop structure 704 is formed over the channel structure 106. In some embodiments, the second etch stop structure 704 may comprise a first etch stop layer 704a and a second etch stop layer 704b respectively formed by one or more deposition processes (e.g., a PVD process, a CVD process, a PE-CVD process, and/or the like). In some embodiments, the second etch stop structure 704 may comprise one or more of silicon nitride, silicon carbide, silicon oxynitride, and/or the like.

A third ILD layer 212c is formed over the second etch stop structure 704. In some embodiments, the third ILD layer 212c may be formed by one or more deposition processes (e.g., a PVD process, a CVD process, a PE-CVD process, and/or the like). In some embodiments, the third ILD layer 212c may comprise one or more of silicon dioxide, SiCOH, PSG, BPSG, BSG, FSG, USG, or the like.

A plurality of source/drain contacts 102-104 are formed within the third ILD layer 212c. In some embodiments, the plurality of source/drain contacts 102-104 are formed by performing a patterning process on the third ILD layer 212c. The patterning process etches through the third ILD layer 212c and the second etch stop structure 704 to form a plurality of source/drain openings 1702. The plurality of source/drain contacts 102-104 are formed within the plurality of source/drain openings 1702. In some embodiments, the plurality of source/drain contacts 102-104 may be formed by forming a source/drain liner and a conductive fill over the source/drain liner. In some embodiments, the plurality of source/drain contacts 102-104 may comprise one or more of tantalum nitride (TaN), titanium nitride (TiN), tungsten (W), aluminum (Al), polysilicon, ruthenium (Ru), cobalt (Co), copper (Cu), and/or the like.

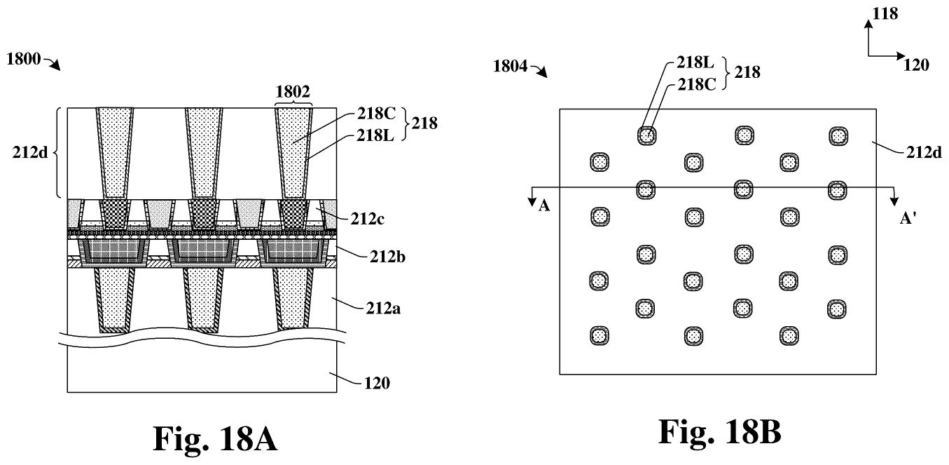

As shown in cross-sectional view 1800 of FIG. 18A and top-view 1804 of FIG. 18B, a first upper ILD structure 212d is formed over the third ILD layer 212c. In some embodiments, the first upper ILD structure 212d may comprise multiple ILD layers stacked onto one another. In some embodiments, the first upper ILD structure 212d may be formed by one or more deposition processes (e.g., a PVD process, a CVD process, a PE-CVD process, and/or the like). In some embodiments, the first upper ILD structure may comprise one or more of silicon dioxide, SiCOH, PSG, BPSG, BSG, FSG, USG, and/or the like.

A patterning process is performed on the first upper ILD structure 212d to form a plurality of upper interconnect openings 1802 respectively formed by sidewalls. In some embodiments, the patterning process may comprise a lithography process followed by an etching process that selectively exposes the first upper ILD structure 212d to an etchant. An upper interconnect liner 218L is formed within the plurality of upper interconnect openings 1802. An upper conductive material 218C is formed on the upper interconnect liner 218L and within the plurality of upper interconnect openings 1802. A planarization process (e.g., a CMP process) is performed to remove parts of the upper interconnect liner 218L and the upper conductive material 218C that are over the first upper ILD structure 212d. The planarization process forms a first plurality of upper interconnects 218 within the first upper ILD structure 212d.

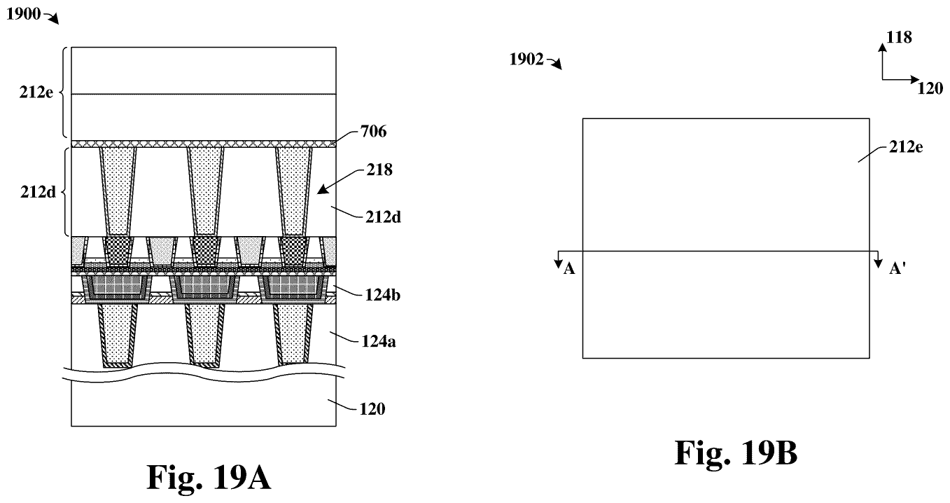

As shown in cross-sectional view 1900 of FIG. 19A and top-view 1902 of FIG. 19B, a third etch stop structure 706 is formed over the first upper ILD structure 212d. In some embodiments, the third etch stop structure 706 may be formed by one or more deposition processes (e.g., a PVD process, a CVD process, a PE-CVD process, and/or the like). In some embodiments, the third etch stop structure 706 may comprise one or more of silicon nitride, silicon carbide, silicon oxynitride, and/or the like.

A second upper ILD structure 212e is formed over the third etch stop structure 706. In some embodiments, the second upper ILD structure 212e may comprise multiple ILD layers stacked onto one another. In some embodiments, the second upper ILD structure 212e may be formed by one or more deposition processes (e.g., a PVD process, a CVD process, a PE-CVD process, and/or the like). In some embodiments, the second upper ILD structure 212e may comprise silicon dioxide, SiCOH, PSG, BPSG, BSG, FSG, USG, and/or the like.

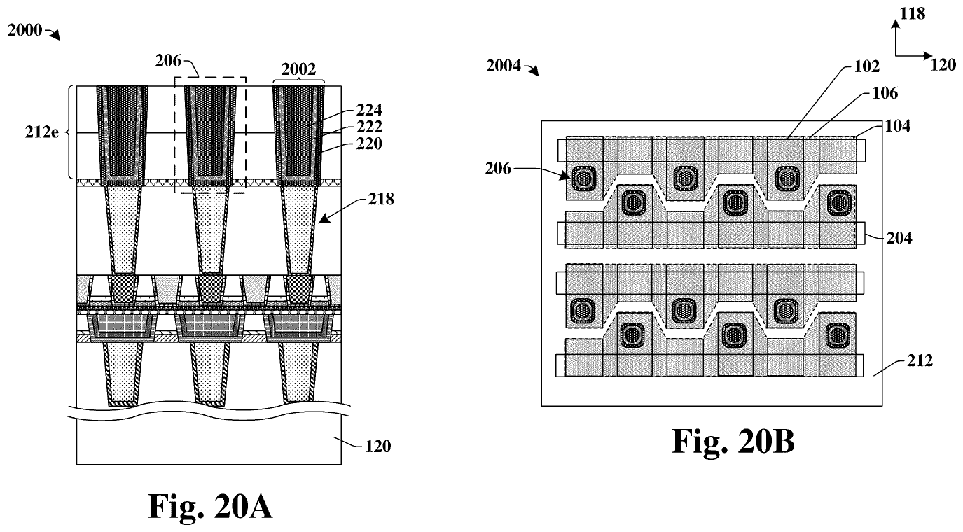

As shown in cross-sectional view 2000 of FIG. 20A and top-view 2004 of FIG. 20B, a patterning process is performed on the second upper ILD structure 212e. The patterning process forms a plurality of capacitor openings 2002 that extend through the second upper ILD structure 212e to expose the first plurality of upper interconnects 218. In some embodiments, the patterning process may comprise a lithography process followed by an etching process that selectively exposes the second upper ILD structure 212e to an etchant.

A lower capacitor electrode 220 is formed within the plurality of capacitor openings 2002. A capacitor dielectric 222 is formed on the lower capacitor electrode 220 and within the plurality of capacitor openings 2002. An upper capacitor electrode 224 is formed on the capacitor dielectric 222 and within the plurality of capacitor openings 2002. A planarization process (e.g., a CMP process) is performed to remove parts of the lower capacitor electrode 220, the capacitor dielectric 222, and the upper capacitor electrode 224 that are over the second upper ILD structure 212e. The planarization process forms a plurality of capacitors 206 within the second upper ILD structure 212e.

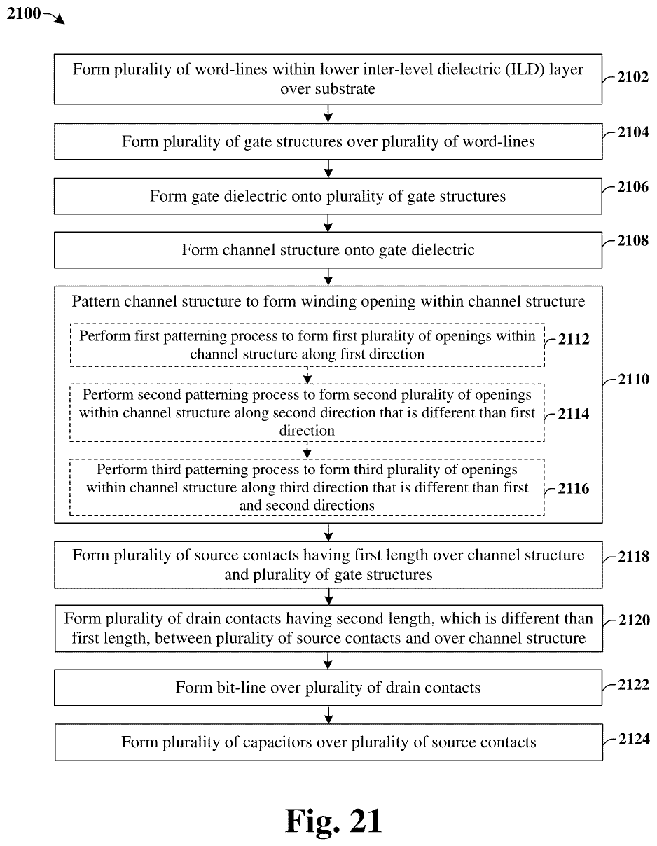

FIG. 21 illustrates a flow diagram of some embodiments of a method 2100 of forming an integrated chip memory structure having access transistor with an asymmetric source/drain design.

While method 2100 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 2102, a plurality of word-lines (e.g., lower interconnect wires) are formed within a lower inter-level dielectric (ILD) layer over a substrate. FIGS. 8A-10B illustrate some embodiments corresponding to act 2104.

At act 2104, a plurality of gate structures are formed over the plurality of word-lines. FIGS. 11A-12B illustrate some embodiments corresponding to act 2102.

At act 2106, a gate dielectric is formed onto the plurality of gate structures. FIGS. 13A-13B illustrate some embodiments corresponding to act 2106.

At act 2108, a channel structure is formed onto the gate dielectric. FIGS. 13A-13B illustrate some embodiments corresponding to act 2108.

At act 2110, the channel structure is patterned to form tortuous opening extending through channel structure. In some embodiments, the channel structure may be patterned according to acts 2112-2116.

At act 2112, a first patterning process is performed to form a first plurality of openings within the channel structure along a first direction. FIGS. 14A-14B illustrate some embodiments corresponding to act 2112.

At act 2114, a second patterning process is performed to form a second plurality of openings within the channel structure along a second direction that is different than the first direction. FIGS. 15A-15B illustrate some embodiments corresponding to act 2114.

At act 2116, a third patterning process is performed to form a third plurality of openings within the channel structure along a third direction that is different than the first direction and the second direction. FIGS. 16A-16B illustrate some embodiments corresponding to act 2116.

At act 2118, a plurality of source contacts having a first length are formed over the channel structure and the plurality of gate structures. FIGS. 17A-17B illustrate some embodiments corresponding to act 2118.

At act 2120, a plurality of drain contacts having a second length, which is different than the first length, are formed between the plurality of source contacts and over the channel structure. FIGS. 17A-17B illustrate some embodiments corresponding to act 2118.

At act 2122, a bit-line is formed over the plurality of drain contacts. FIGS. 19A-20B illustrate some embodiments corresponding to act 2122.

At act 2124, a plurality of capacitors are formed over the plurality of source contacts. FIGS. 19A-20B illustrate some embodiments corresponding to act 2124.

Accordingly, in some embodiments, the present disclosure relates to an integrated chip memory structure having an access transistor with asymmetric source/drain contacts.

In some embodiments, the present disclosure relates to an integrated chip. The integrated chip includes a gate structure over a substrate; a channel structure over the gate structure; a first source/drain contact and a second source/drain contact disposed over the channel structure and the gate structure, the first source/drain contact being laterally separated from the second source/drain contact along a first direction; a capacitor electrically coupled to the first source/drain contact; and wherein the first source/drain contact has a first length and the second source/drain contact has a second length measured along a second direction that is substantially perpendicular to the first direction, the first length being different than the second length. In some embodiments, the first source/drain contact laterally extends from next to the second source/drain contact to a non-zero distance past an end of the second source/drain contact in a plan-view. In some embodiments, the channel structure has a first width below the first source/drain contact and a second width below the second source/drain contact, the first width being different than the second width. In some embodiments, the channel structure has an angled sidewall that extends between the first source/drain contact and the second source/drain contact, the angled sidewall being oriented at an acute angle with respect to a sidewall of the first source/drain contact as viewed in a plan-view. In some embodiments, the channel structure varies between a first width directly below the first source/drain contact and a second width directly below the second source/drain contact, the first width being different than the second width. In some embodiments, the integrated chip further includes a bit-line coupled to the second source/drain contact, the bit-line having a first width that is substantially equal to the second length of the second source/drain contact. In some embodiments, the first width of the bit-line is smaller than the first length of the first source/drain contact. In some embodiments, the integrated chip further includes a bit-line coupled to the second source/drain contact, the bit-line having a width that is less than the first length of the first source/drain contact and the second length of the second source/drain contact. In some embodiments, the integrated chip further includes a second gate structure disposed over the substrate; a second channel structure arranged over the second gate structure; a third source/drain contact and a fourth source/drain contacts disposed over the second channel structure and the second gate structure; and the channel structure being separated from the second channel structure by a region having a serpentine shape as viewed in a plan-view.

In other embodiments, the present disclosure relates to method of forming an integrated chip. The method includes forming a gate structure over a substrate; forming a channel structure over the gate structure; performing a first patterning process on the channel structure to remove first segments of the channel structure extending along a first direction; performing a second patterning process on the channel structure to remove second segments of the channel structure extending along a second direction that is different than the first direction; performing a third patterning process on the channel structure to remove third segments of the channel structure extending along a third direction that is different than the first direction and the second direction; and forming a first source/drain contact and a second source/drain contact over the gate structure and the channel structure. In some embodiments, the first segments and the second segments are contiguous with the third segments. In some embodiments, removal of the first segments, the second segments, and the third segments collectively form a serpentine opening extending through the channel structure along first sides of the first source/drain contact and the second source/drain contact. In some embodiments, removal of the first segments further form a straight opening extending through the channel structure along second sides of the first source/drain contact and the second source/drain contact, the second sides opposing the first sides. In some embodiments, the first source/drain contact and the second source/drain contact have ends that are aligned with one another. In some embodiments, the gate structure is laterally surrounded by an inter-level dielectric (ILD) layer. In some embodiments, the first segments are oriented at an acute angle with respect to the second segments as viewed in a plan-view. In some embodiments, the first patterning process, the second patterning process, and the third patterning process respectively include a lithographic exposure and a development process.

In yet other embodiments, the present disclosure relates to a method of forming an integrated chip. The method includes forming a gate structure over a substrate; forming a channel structure over the gate structure, the channel structure having a width that varies between a first width and a second width; forming a first source/drain contact over a first part of the channel structure having the first width; and forming a second source/drain contact over a second part of the channel structure having the second width. In some embodiments, the first source/drain contact is separated from the second source/drain contact along a first direction; and the first source/drain contact has a first length and the second source/drain contact has a second length measured along a second direction that is substantially perpendicular to the first direction, the first length being different than the second length. In some embodiments, the channel structure comprises one or more of indium-gallium-zinc-oxide, zinc oxide, indium oxide, tin oxide, nickel oxide, copper oxide, copper aluminum oxide, copper gallium oxide, copper indium oxide, and strontium copper oxide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a gate structure over a substrate;
a channel structure over the gate structure;
a first source/drain contact and a second source/drain contact disposed over the channel structure and the gate structure, wherein the first source/drain contact is laterally separated from the second source/drain contact along a first direction;
a capacitor electrically coupled to the first source/drain contact; and
wherein the first source/drain contact has a first length and the second source/drain contact has a second length measured along a second direction that is substantially perpendicular to the first direction, the first length being different than the second length.

2. The integrated chip of claim 1, wherein the first source/drain contact laterally extends from next to the second source/drain contact to a non-zero distance past an end of the second source/drain contact in a plan-view.

3. The integrated chip of claim 1, wherein the channel structure has a first width below the first source/drain contact and a second width below the second source/drain contact, the first width being different than the second width.

4. The integrated chip of claim 1, wherein the channel structure has an angled sidewall that extends between the first source/drain contact and the second source/drain contact, the angled sidewall being oriented at an acute angle with respect to a sidewall of the first source/drain contact as viewed in a plan-view.

5. The integrated chip of claim 1, wherein the channel structure varies between a first width directly below the first source/drain contact and a second width directly below the second source/drain contact, the first width being different than the second width.

6. The integrated chip of claim 1, further comprising:
a bit-line coupled to the second source/drain contact, wherein the bit-line has a first width that is substantially equal to the second length of the second source/drain contact.

7. The integrated chip of claim 6, wherein the first width of the bit-line is smaller than the first length of the first source/drain contact.

8. The integrated chip of claim 1, further comprising:
a bit-line coupled to the second source/drain contact, wherein the bit-line has a width that is less than the first length of the first source/drain contact and the second length of the second source/drain contact.

9. The integrated chip of claim 1, further comprising:
a second gate structure disposed over the substrate;
a second channel structure arranged over the second gate structure;
a third source/drain contact and a fourth source/drain contacts disposed over the second channel structure and the second gate structure; and
wherein the channel structure is separated from the second channel structure by a region having a serpentine shape as viewed in a plan-view.

10. A method of forming an integrated chip, comprising:
forming a gate structure over a substrate;
forming a channel structure over the gate structure;
performing a first patterning process on the channel structure to remove first segments of the channel structure extending along a first direction;
performing a second patterning process on the channel structure to remove second segments of the channel structure extending along a second direction that is different than the first direction;
performing a third patterning process on the channel structure to remove third segments of the channel structure extending along a third direction that is different than the first direction and the second direction; and
forming a first source/drain contact and a second source/drain contact over the gate structure and the channel structure.

11. The method of claim 10, wherein the first segments and the second segments are contiguous with the third segments.

12. The method of claim 10, wherein removal of the first segments, the second segments, and the third segments collectively form a serpentine opening extending through the channel structure along first sides of the first source/drain contact and the second source/drain contact.

13. The method of claim 12, wherein removal of the first segments further form a straight opening extending through the channel structure along second sides of the first source/drain contact and the second source/drain contact, the second sides opposing the first sides.

14. The method of claim 10, wherein the first source/drain contact and the second source/drain contact have ends that are aligned with one another.

15. The method of claim 10, wherein the gate structure is laterally surrounded by an inter-level dielectric (ILD) layer.

16. The method of claim 10, wherein the first segments are oriented at an acute angle with respect to the second segments as viewed in a plan-view.

17. The method of claim 10, wherein the first patterning process, the second patterning process, and the third patterning process respectively comprise a lithographic exposure and a development process.

18. A method of forming an integrated chip, comprising:
forming a gate structure over a substrate;
forming a channel structure over the gate structure, wherein the channel structure has a width that varies between a first width and a second width;
forming a first source/drain contact over a first part of the channel structure having the first width; and
forming a second source/drain contact over a second part of the channel structure having the second width.

19. The method of claim 18,
wherein the first source/drain contact is separated from the second source/drain contact along a first direction; and
wherein the first source/drain contact has a first length and the second source/drain contact has a second length measured along a second direction that is substantially perpendicular to the first direction, the first length being different than the second length.

20. The method of claim 18, wherein the channel structure comprises one or more of indium-gallium-zinc-oxide, zinc oxide, indium oxide, tin oxide, nickel oxide, copper oxide, copper aluminum oxide, copper gallium oxide, copper indium oxide, and strontium copper oxide.
